(19) United States
(12) Patent Application Publication
(10) Pub. No.: US 2024/0235149 A1
(43) Pub. Date: Jul. 11, 2024

(54) LASER APPARATUS AND ELECTRONIC DEVICE MANUFACTURING METHOD

(71) Applicant: Gigaphoton Inc., Tochigi (JP)

(72) Inventors: Hironori IGARASHI, Oyama-shi (JP); Osamu WAKABAYASHI, Oyama-shi (JP); Yousuke FUJIMAKI, Oyama-shi (JP); Toru SUZUKI, Oyama-shi (JP)

(73) Assignee: Gigaphoton Inc., Tochigi (JP)

(21) Appl. No.: 18/617,704

(22) Filed: Mar. 27, 2024

Related U.S. Application Data
(63) Continuation of application No. PCT/JP2021/042130, filed on Nov. 16, 2021.

(51) Int. Cl. H01S 3/23; H01S 3/02; H01S 3/06; H01S 3/225

(52) U.S. Cl. CPC H01S 3/2333; H01S 3/025; H01S 3/0602; H01S 3/2251; H01S 3/2383

(57) ABSTRACT

A laser apparatus includes an oscillator that outputs laser light, an amplifier, a front optical system and a rear optical system that are disposed at positions where the front and rear optical systems face each other with a chamber sandwiched therebetween and constitute a ring resonator having a first optical path and a second optical path, and first plane parallel substrates disposed on the first optical path or the second optical path. The first optical path is an optical path along which the front optical system outputs the laser light. The second optical path is an optical path along which the rear optical system outputs the laser light. The first plane parallel substrates translate the first optical path and the second optical path, respectively, in the directions in which the first and second optical paths approach each other on the side facing the chamber.

### CROSS-REFERENCE TO RELATED APPLICATIONS

The present application is a continuation application of International Application No. PCT/JP2021/042130, filed on Nov. 16, 2021, the entire contents of which are hereby incorporated by reference.

### BACKGROUND

### 1. Technical Field

The present disclosure relates to a laser apparatus and an electronic device manufacturing method.

### 2. Related Art

In recent years, a semiconductor exposure apparatus is required to improve the resolution thereof as semiconductor integrated circuits are increasingly miniaturized and highly integrated. To this end, reduction in the wavelength of light emitted from a light source for exposure is underway. For example, a KrF excimer laser apparatus, which outputs laser light having a wavelength of about 248 nm, and an ArF excimer laser apparatus, which outputs laser light having a wavelength of about 193 nm, are used as a gas laser apparatus for exposure.

The light from spontaneously oscillating KrF and ArF excimer laser apparatuses has a wide spectral linewidth ranging from 350 to 400 pm. A projection lens made of a material that transmits ultraviolet light, such as KrF and ArF laser light, therefore produces chromatic aberrations in some cases. As a result, the resolution of the projection lens may decrease. To avoid the decrease in the resolution, the spectral linewidth of the laser light output from the gas laser apparatus needs to be narrow enough to make the chromatic aberrations negligible. To this end, a line narrowing module (LNM) including a line narrowing element (etalon or grating) is provided in some cases in a laser resonator of the gas laser apparatus to narrow the spectral linewidth. A gas laser apparatus providing a narrowed spectral linewidth is hereinafter referred to as a narrowed-line gas laser apparatus.

### CITATION LIST

### Patent Literature

[PTL 1] U.S. patent application Publication No. 2008/0117948

### SUMMARY

A laser apparatus according to an aspect of the present disclosure includes an oscillator configured to output laser light, an amplifier configured to amplify the laser light in a chamber including a pair of discharge electrodes, a front optical system and a rear optical system that are disposed at positions where the front and rear optical systems face each other with the chamber sandwiched therebetween and constitute a ring resonator having a first optical path and a second optical path that intersect with each other between the pair of discharge electrodes, and a first plane parallel substrate disposed on the first or second optical path, the first optical path being an optical path via which the front optical system outputs the laser light incident from the oscillator toward the rear optical system, the second optical path being an optical path via which the rear optical system outputs the laser light incident via the first optical path toward the front optical system, and the first plane parallel substrate configured to translate the first and second optical paths in such a way that the first and second optical paths approach each other on a side facing the chamber.

An electronic device manufacturing method according to an aspect of the present disclosure is an electronic device manufacturing method including generating laser light by using a laser apparatus, outputting the laser light to an exposure apparatus, and exposing a photosensitive substrate to the laser light in the exposure apparatus to manufacture electronic devices, the laser apparatus including an oscillator configured to output laser light, an amplifier configured to amplify the laser light in a chamber including a pair of discharge electrodes, a front optical system and a rear optical system that are disposed at positions where the front and rear optical systems face each other with the chamber sandwiched therebetween and constitute a ring resonator having a first optical path and a second optical path that intersect with each other between the pair of discharge electrodes, and a first plane parallel substrate disposed on the first or second optical path, the first optical path being an optical path via which the front optical system outputs the laser light incident from the oscillator toward the rear optical system, the second optical path being an optical path via which the rear optical system outputs the laser light incident via the first optical path toward the front optical system, and the first plane parallel substrate configured to translate the first and second optical paths in such a way that the first and second optical paths approach each other on a side facing the chamber.

### BRIEF DESCRIPTION OF DRAWINGS

Embodiments of the present disclosure will be described below only by way of example with reference to the accompanying drawings.

FIG. 1 is a front view schematically showing the configuration of a laser apparatus according to Comparative Example.

FIG. 2 is a top view schematically showing an example of the configuration of a power oscillator according to Comparative Example.

FIG. 3 is a top view schematically showing an example of the configuration of a power oscillator according to a first embodiment.

FIG. 4 is a perspective view schematically showing the configuration of first and second plane parallel substrates.

FIG. 5 describes an effect of the first and second plane parallel substrates.

FIG. 6 is a top view schematically showing an example of the configuration of a power oscillator according to a variation of the first embodiment.

FIG. 7 is a top view schematically showing an example of the configuration of a power oscillator according to a second embodiment.

FIG. 8 is a top view schematically showing an example of the configuration of a power oscillator according to a third embodiment.

FIG. 9 is a top view schematically showing an example of the configuration of a power oscillator according to a fourth embodiment.

FIG. 10 shows the structure of a CaF₂ crystal that forms the first plane parallel substrate.

FIG. 11 shows a first preferable crystal orientation in relation to laser light incident on the first plane parallel substrate.

FIG. 12 shows a second preferable crystal orientation in relation to the laser light incident on the first plane parallel substrate.

FIG. 13 shows a third preferable crystal orientation in relation to the laser light incident on the first plane parallel substrate.

FIG. 14 is a front view schematically showing an example of the configuration of a laser apparatus according to a variation.

FIG. 15 schematically shows an example of the configuration of an exposure apparatus.

### DETAILED DESCRIPTION

### Contents

1. Comparative Example
1.1 Configuration
1.2 Operation
1.3 Problems
2. First embodiment
2.1 Configuration
2.2 Operation
2.3 Effects
2.4 Variations
3. Second embodiment
3.1 Configuration
3.2 Operation
3.3 Effects
4. Third embodiment
4.1 Configuration
4.2 Operation
4.3 Effects
4.4 Variations
5. Fourth embodiment
5.1 Configuration
5.2 Operation
5.3 Effects
5.4 Variations
6. Crystal orientation of plane parallel substrates
6.1 Crystal structure
6.2 First crystal orientation
6.3 Second crystal orientation
6.4 Third crystal orientation
7. Variation of master oscillator
7.1 Configuration
7.2 Operation
7.3 Others
8. Electronic device manufacturing method

Embodiments of the present disclosure will be described below in detail with reference to the drawings. The embodiments described below show some examples of the present disclosure and are not intended to limit the contents of the present disclosure. Furthermore, all configurations and operations described in the embodiments are not necessarily essential as configurations and operations in the present disclosure. The same component has the same reference character, and no redundant description of the same component will be made.

### 1. Comparative Example

### 1.1 Configuration

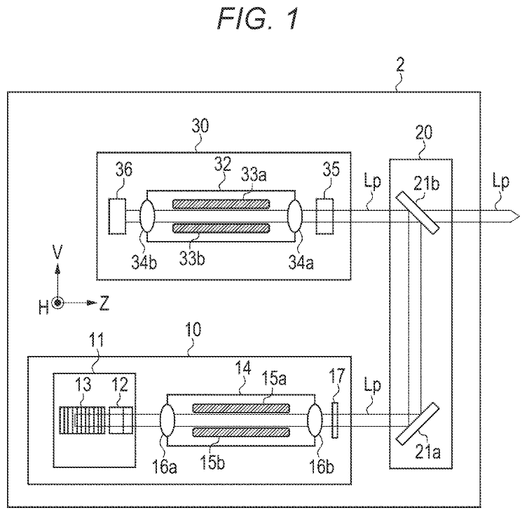

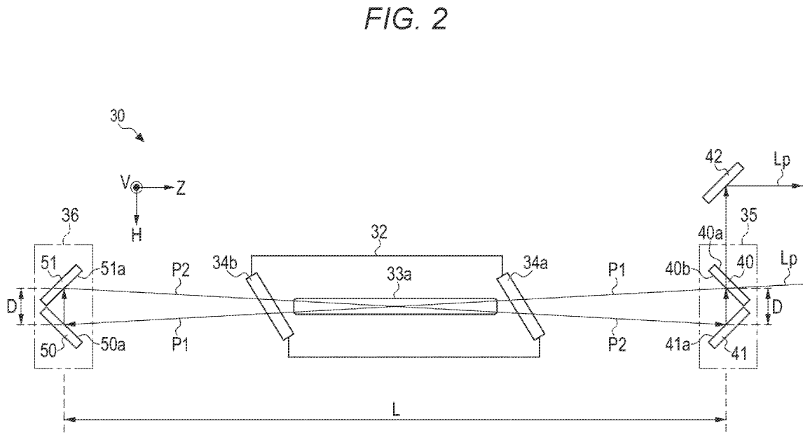

FIG. 1 schematically shows an example of the configuration of a laser apparatus 2 according to Comparative Example. FIG. 2 schematically shows an example of the configuration of a power oscillator 30 according to Comparative Example. Comparative Example in the present disclosure is an aspect that the applicant is aware of as known only by the applicant, and is not a publicly known example that the applicant is self-aware of.

In FIG. 1, it is assumed that a V-axis direction is the height direction of the laser apparatus 2, a Z-axis direction is the length direction thereof, and an H-axis direction is the depth direction thereof. The V-axis direction may be parallel to the direction of gravity, and “the direction toward the positive end of the V-axis” is assumed to be the direction opposite to the direction of gravity. “The direction toward the positive end of the Z-axis direction” is assumed to be the direction in which laser light Lp output from the laser apparatus 2 exits. “The direction toward the positive end of the H-axis direction” is assumed to be the direction in the plane of view of FIG. 1 toward the reader of the specification.

The laser apparatus 2 includes a master oscillator (MO) 10, an MO beam steering unit 20, and the power oscillator (PO) 30. Note that the master oscillator 10 is an example of the “oscillator” according to the technology of the present disclosure. The power oscillator 30 is an example of the “amplifier” according to the technology of the present disclosure.

The master oscillator 10 includes a line narrowing module (LNM) 11, a chamber 14, and an output coupler (OC) 17.

The LNM 11 includes a prism beam expander 12 and a grating 13, which narrow the spectral linewidth. The prism beam expander 12 and the grating 13 are disposed in the Littrow arrangement, which causes the angle of incidence of the light incident on the grating 13 to be equal to the angle of diffraction of the light diffracted by the grating 13.

The output coupler 17 is a reflective mirror having a reflectance ranging from 40% to 60%. The output coupler 17 and the LNM 11 constitute an optical resonator.

The chamber 14 is disposed on the optical path of the optical resonator. The chamber 14 includes a pair of discharge electrodes 15a and 15b and two windows 16a and 16b, through which the laser light Lp passes. The chamber 14 is filled with a laser gas. The laser gas may contain, for example, an Ar or Kr gas as a rare gas, an F₂ gas as a halogen gas, and an Ne gas as a buffer gas.

The windows 16a and 16b are so disposed that the angle of incidence of the laser light Lp incident thereon is close to Brewster's angle. The windows 16a and 16b are further so disposed that the laser light Lp is P-polarized light.

The MO beam steering unit 20 includes highly reflective mirrors 21a and 21b. The highly reflective mirrors 21a and 21b are so disposed that the laser light Lp output from the master oscillator 10 enters the power oscillator 30. The laser light Lp output from the master oscillator 10 is pulse laser light.

A highly reflective mirror in the present disclosure is, for example, a planar mirror including a substrate made of synthetic quartz or calcium fluoride (CaF₂) and having a surface on which a highly reflective film is formed. The highly reflective film is a dielectric multilayer film, for example, a film containing fluoride.

The power oscillator 30 includes a chamber 32, a front optical system 35, and a rear optical system 36. The front optical system 35 and the rear optical system 36 constitute a ring resonator. The front optical system 35 is disposed on the light input side where the laser light Lp enters the power oscillator 30 from the MO beam steering unit 20. The rear optical system 36 is disposed at a position where the rear optical system 36 faces the front optical system 35 with the chamber 32 therebetween.

The chamber 32 is disposed on the optical path of the ring resonator. The chamber 32 has the same configuration as the chamber 14 of the master oscillator 10 has. That is, the chamber 32 includes a pair of discharge electrodes 33a and 33b and two windows 34a and 34b, through which the laser light Lp passes. The chamber 32 is filled with a laser gas.

The windows 34a and 34b are so disposed that the angle of incidence of the laser light Lp incident thereon is close to Brewster's angle. The windows 34a and 34b are further so disposed that the laser light Lp is P-polarized light.

In FIG. 2, the front optical system 35 includes an output coupler 40 and a highly reflective mirror 41. The output coupler 40 is so disposed on the optical path of the laser light Lp incident from the MO beam steering unit 20 that the laser light Lp is incident on the output coupler 40 at a predetermined angle of incidence.

The output coupler 40 is, for example, a partially reflective mirror having a reflectance ranging from 10% to 30%. The output coupler 40 has a first surface 40a and a second surface 40b facing each other. The first surface 40a and the second surface 40b are parallel to the V-axis direction, which is the direction in which discharge occurs between the pair of discharge electrodes 33a and 33b. The first surface 40a is coated with an anti-reflection film. The second surface 40b is coated with a partially reflective film.

The output coupler 40 transmits the laser light Lp incident on the first surface 40a from the MO beam steering unit 20. Furthermore, the output coupler 40 transmits part of the laser light Lp incident on the second surface 40b from the highly reflective mirror 41 and reflects part of the laser light Lp. The above-mentioned part of the laser light Lp having passed through the output coupler 40 exits out of the front optical system 35 and is incident on a highly reflective mirror 42, which will be described later. The part of the laser light Lp reflected off the second surface 40b of the output coupler 40 enters the chamber 32.

The highly reflective mirror 41 has a highly reflective surface 41a coated with a highly reflective film. The output coupler 40 and the highly reflective mirror 41 are so disposed that the second surface 40b and the highly reflective surface 41a face each other with the two mirrors inclining with respect to each other by a predetermined angle. The highly reflective surface 41a of the highly reflective mirror 41 reflects the laser light Lp, which is incident from the rear optical system 36 via the chamber 32, toward the second surface 40b of the output coupler 40.

Although omitted in FIG. 1, the highly reflective mirror 42 is disposed on the light exiting side of the front optical system 35, as shown in FIG. 2. The highly reflective mirror 42 reflects the laser light Lp output from the front optical system 35 and causes the laser light Lp to travel in the Z-axis direction.

The rear optical system 36 includes a first highly reflective mirror 50 and a second highly reflective mirror 51. The first highly reflective mirror 50 has a highly reflective surface 50a coated with a highly reflective film. The second highly reflective mirror 51 has a highly reflective surface 51a coated with a highly reflective film. The highly reflective surfaces 50a and 51a are parallel to the V-axis direction. The first highly reflective mirror 50 and the second highly reflective mirror 51 are so disposed that the highly reflective surfaces 50a and 51a face each other with the two mirrors inclining with respect to each other by a predetermined angle.

The highly reflective surface 50a of the first highly reflective mirror 50 reflects the laser light Lp, which is incident from the front optical system 35 via the chamber 32, toward the second highly reflective mirror 51. The highly reflective surface 51a of the second highly reflective mirror 51 reflects the laser light Lp, which is incident from the first highly reflective mirror 50, toward the chamber 32.

The front optical system 35 and the rear optical system 36 constitute a ring resonator including a first optical path P1 and a second optical path P2, which intersect with each other between the pair of discharge electrodes 33a and 33b. The first optical path P1 and the second optical path P2 are close to each other in the discharge space between the pair of discharge electrodes 33a and 33b.

The first optical path P1 includes the output coupler 40 and the first highly reflective mirror 50. The second optical path P2 includes the second highly reflective mirror 51 and the highly reflective mirror 41. The first optical path P1 is the optical path along which the front optical system 35 outputs the laser light Lp, which is incident from the master oscillator 10, toward the rear optical system 36. The second optical path P2 is the optical path along which the rear optical system 36 outputs the laser light Lp, which is incident via the first optical path P1, toward the front optical system 35.

That is, the first optical path P1 is an outward path extending from the front optical system 35 to the rear optical system 36 via the chamber 32. The second optical path P2 is a return path extending from the rear optical system 36 to the front optical system 35 via the chamber 32. The first optical path P1 and the second optical path P2 are contained in a plane perpendicular to the V-axis direction, which is the direction in which discharge occurs between the pair of discharge electrodes 33a and 33b.

### 1.2 Operation

When discharge occurs in the chamber 14 of the master oscillator 10, the laser gas is excited, and the laser light Lp having a linewidth narrowed by the optical resonator including the output coupler 17 and the LNM 11 is output via the output coupler 17. The MO beam steering unit 20 causes the laser light Lp to enter as seed light the front optical system 35 of the power oscillator 30.

The laser light Lp having entered the front optical system 35 passes through the output coupler 40 and enters the ring resonator. The laser light Lp having passed through the output coupler 40 travels along the first optical path P1 and enters the chamber 32. In synchronization with the timing at which the laser light Lp enters the chamber 32, discharge occurs in the discharge space. As a result, the laser gas is excited, and the laser light Lp is amplified. The amplified laser light Lp exits out of the chamber 32, travels along the first optical path P1, and then enters the rear optical system 36.

The laser light Lp having entered the rear optical system 36 is reflected off the first highly reflective mirror 50 and the second highly reflective mirror 51, which cause the laser light Lp to travel back toward the front optical system 35, and exits out of the rear optical system 36. The laser light Lp having exited out of the rear optical system 36 travels along the second optical path P2 and enters the chamber 32. The laser light Lp having entered the chamber 32 is amplified again in the discharge space and exits out of the chamber 32. The laser light Lp having exited out of the chamber 32 travels along the second optical path P2 and enters the front optical system 35.

The laser light Lp having entered the front optical system 35 is reflected off the highly reflective mirror 41 toward the output coupler 40. Part of the laser light Lp incident on the output coupler 40 passes through the output coupler 40 and exits out of the front optical system 35 toward the highly reflective mirror 42, is reflected off the highly reflective mirror 42, and hence exits out of the laser apparatus 2.

The remainder of the laser light Lp incident on the output coupler 40 is reflected off the output coupler 40 and hence output from the front optical system 35 toward the chamber 32. That is, the front optical system 35 causes the remainder of the laser light Lp to travel back toward the rear optical system 36. The laser light Lp traveling back toward the rear optical system 36 travels again along the first optical path P1 and enters the chamber 32. Part of the laser light Lp thus repeatedly circle the ring resonator having the first optical path P1 and the second optical path P2. The laser light Lp undergoes amplified oscillation when passing through the discharge space multiple times in a single discharge period.

### 1.3 Problems

In the power oscillator 30 of the laser apparatus 2 according to Comparative Example, a spacing D between the first optical path P1 and the second optical path P2 at the opposite ends thereof needs to be greater than or equal to a certain value to allow the front optical system 35 to cause the laser light Lp to travel back toward the rear optical system 36 and vice versa. The reason for this is that the front optical system 35 and the rear optical system 36 are difficult to be designed when the spacing D is small. The spacing D between the first optical path P1 and the second optical path P2 at the opposite ends thereof is hereinafter called an optical path end spacing D.

To efficiently amplify the laser light Lp in the discharge space, it is necessary to cause the first optical path P1 and the second optical path P2 to intersect with each other at a small angle to cause the first optical path P1 and the second optical path P2 to be close to each other in the discharge space. Therefore, to achieve the optical path end spacing D required to cause the laser light Lp to travel back, a resonator length L of the power oscillator 30 needs to be longer than or equal to a certain length. The resonator length L refers to the length of the ring resonator in the Z-axis direction.

Increasing the resonator length L, however, increases the circling period required for the laser light Lp to circle the ring resonator, and hence reduces the number of times the laser light Lp passes through the discharge space in a single discharge period. As a result, the amplification efficiency decreases.

To improve the amplification efficiency, it is required to shorten the resonator length L while causing the first optical path P1 and the second optical path P2 to be close to each other in the discharge space.

### 2. First Embodiment

### 2.1 Configuration

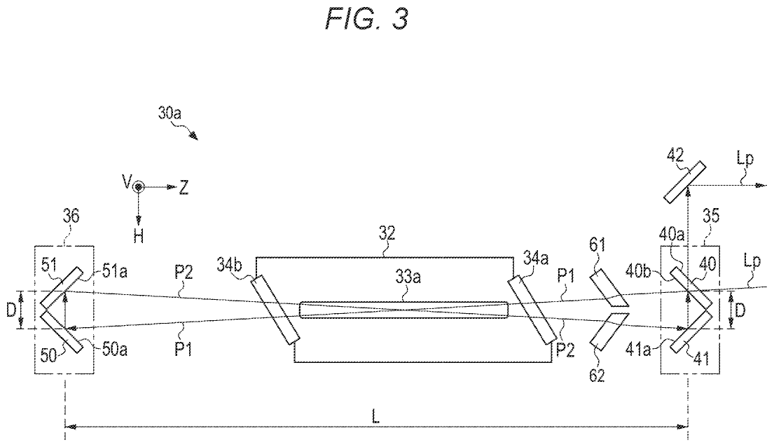

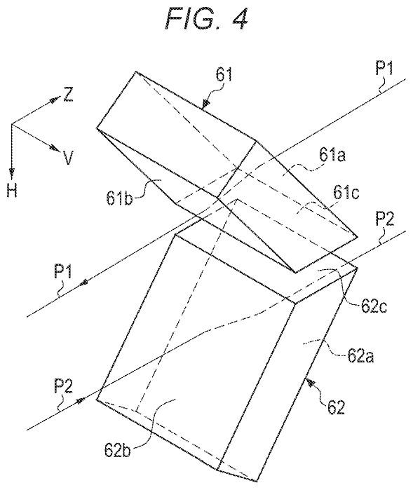

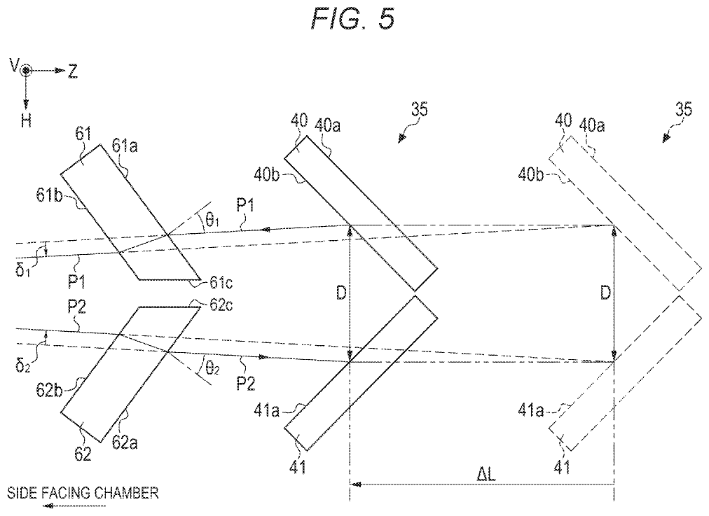

FIG. 3 schematically shows an example of the configuration of a power oscillator 30a accommodated in the laser apparatus according to a first embodiment of the present disclosure. FIG. 4 shows the configuration of a first plane parallel substrate 61 and a second plane parallel substrate 62. FIG. 5 describes an effect of the first plane parallel substrate 61 and the second plane parallel substrate 62. The laser apparatus according to the first embodiment differs from the laser apparatus 2 according to Comparative Example only in that the power oscillator 30a is configured differently.

In FIG. 3, the power oscillator 30a includes the chamber 32, the front optical system 35, the rear optical system 36, the first plane parallel substrate 61, and the second plane parallel substrate 62. The power oscillator 30a differs from the power oscillator 30 according to Comparative Example in that the power oscillator 30a includes the first plane parallel substrate 61 and the second plane parallel substrate 62. The configurations of the chamber 32, the front optical system 35, and the rear optical system 36 accommodated in the power oscillator 30a are the same as those in Comparative Example.

The first plane parallel substrate 61 and the second plane parallel substrate 62 are each a plane parallel substrate transparent to the laser light Lp. The first plane parallel substrate 61 and the second plane parallel substrate 62 are made, for example, of calcium fluoride (CaF₂).

In the present embodiment, the first plane parallel substrate 61 and the second plane parallel substrate 62 are disposed between the chamber 32 and the front optical system 35. Specifically, the first plane parallel substrate 61 is disposed on the first optical path P1 facing the front of the chamber 32. The second plane parallel substrate 62 is disposed on the second optical path P2 facing the front of the chamber 32. The first optical path P1 facing the front of the chamber 32 refers to the first optical path P1 between the chamber 32 and the front optical system 35. The second optical path P2 facing the front of the chamber 32 refers to the second optical path P2 between the chamber 32 and the front optical system 35.

In FIG. 4, the first plane parallel substrate 61 has a first surface 61a and a second surface 61b, which face each other, and a third surface 61c. The first surface 61a and the second surface 61b are planar surfaces parallel to each other and parallel to the V-axis direction. The third surface 61c is an inclining surface inclining with respect to the first surface 61a and the second surface 61b and is a planar surface parallel to the V-axis and Z-axis directions. The side surface of the first plane parallel substrate 61 has a trapezoidal shape when viewed in the V-axis direction.

The second plane parallel substrate 62 has a first surface 62a and a second surface 62b, which face each other, and a third surface 62c. The first surface 62a and the second surface 62b are planar surfaces parallel to each other and parallel to the V-axis direction. The third surface 62c is an inclining surface inclining with respect to the first surface 62a and the second surface 62b and is a planar surface parallel to the V-axis and Z-axis directions. The side surface of the second plane parallel substrate 62 has a trapezoidal shape when viewed in the V-axis direction.

The first plane parallel substrate 61 and the second plane parallel substrate 62 are, for example, plane parallel substrates having the same shape and size. The first plane parallel substrate 61 and the second plane parallel substrate 62 are so disposed that the third surface 61c and the third surface 62c are separate from each other, and that the second surface 61b and the second surface 62b face each other with the surfaces inclining with respect to each other by a predetermined angle. Configuring the first plane parallel substrate 61 and the second plane parallel substrate 62 as described above allows the plane parallel substrates to be disposed on the first optical path P1 and the second optical path P2 in the narrow space in the ring resonator for space saving.

The first plane parallel substrate 61 is so disposed that a normal to the first surface 61a intersects with the first optical path P1 at an angle θ₁, as shown in FIG. 5. The angle θ₁ is, for example, Brewster's angle. That is, the angle of incidence of the laser light Lp incident on the first plane parallel substrate 61 is Brewster's angle. The first plane parallel substrate 61 translates the first optical path P1 by a distance δ₁. Specifically, the first plane parallel substrate 61 translates the first optical path P1 by the distance δ₁ in the direction in which the first optical path P1 approaches the second optical path P2 on the side facing the chamber 32. The distance δ₁ is a value determined in accordance with the angle θ₁ and the refractive index and thickness of the first plane parallel substrate 61.

The second plane parallel substrate 62 is so disposed that a normal to the first surface 62a intersects with the second optical path P2 at an angle θ₂. The angle θ₂ is, for example, Brewster's angle. That is, the angle of incidence of the laser light Lp incident on the second plane parallel substrate 62 is Brewster's angle. The second plane parallel substrate 62 translates the second optical path P2 by a distance δ₂. Specifically, the second plane parallel substrate 62 translates the second optical path P2 by the distance δ₂ in the direction in which the second optical path P2 approaches the first optical path P1 on the side facing the chamber 32. The distance δ₂ is a value determined in accordance with the angle θ₂ and the refractive index and thickness of the second plane parallel substrate 62. In the present embodiment, δ₂ is equal to δ₂.

That is, the first plane parallel substrate 61 and the second plane parallel substrate 62 translate the first optical path P1 and the second optical path P2, respectively, on the side facing the front of the chamber 32 in the directions in which the two optical paths approach each other on the side facing the chamber 32.

### 2.2 Operation

The operation of the laser apparatus according to the first embodiment is the same as that of the laser apparatus 2 according to Comparative Example except that the laser light Lp circling the ring resonator is shifted in the power oscillator 30a by the first plane parallel substrate 61 and the second plane parallel substrate 62.

In the present embodiment, the laser light Lp output from the front optical system 35 and traveling along the first optical path P1 is shifted when passing through the first plane parallel substrate 61, and enters the chamber 32. The laser light Lp output from the chamber 32 and traveling along the second optical path P2 is shifted when passing through the second plane parallel substrate 62, and enters the front optical system 35.

### 2.3 Effects

In FIG. 5, the position of the front optical system 35 in Comparative Example is indicated by the broken lines, and the position of the front optical system 35 in the present embodiment is indicated by the solid lines. In the present embodiment, the first plane parallel substrate 61 and the second plane parallel substrate 62 translate the first optical path P1 and the second optical path P2, respectively, in the directions in which the two optical paths approach each other on the side facing the chamber 32, so that the position where the optical path end spacing D required to cause the laser light Lp to travel back is achieved can approach the chamber 32.

Therefore, in the present embodiment, the front optical system 35 can be closer to the chamber 32 than in Comparative Example. As a result, the resonator length L can be shortened with the first optical path P1 and the second optical path P2 being close to each other in the discharge space. A distance ΔL, by which the resonator length L can be shortened, depends on the distances δ₁ and δ₂ described above and the angle at which the first optical path P1 and the second optical path P2 intersect with each other.

Reducing the resonator length L shortens the circling period, for which the laser light Lp circles the ring resonator, and hence increases the number of times the laser light Lp passes through the discharge space in a single discharge period. As a result, the amplification efficiency improves.

### 2.4 Variations

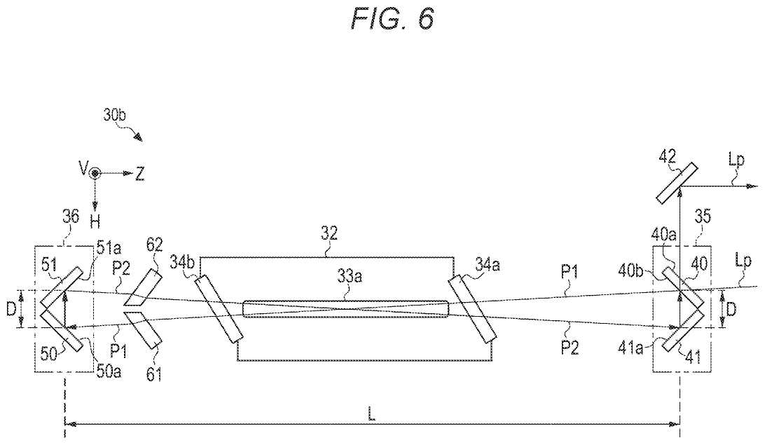

A variation of the power oscillator 30a according to the first embodiment will next be described. FIG. 6 schematically shows an example of the configuration of a power oscillator 30b according to the variation. The first plane parallel substrate 61 and the second plane parallel substrate 62 are disposed on the side facing the front of the chamber 32 in the first embodiment, and are disposed on the side facing the rear of the chamber 32 in the present variation. The power oscillator 30b has a configuration that is the same as that of the power oscillator 30a according to the first embodiment except that the first plane parallel substrate 61 and the second plane parallel substrate 62 are differently disposed.

The first plane parallel substrate 61 and the second plane parallel substrate 62 shown in FIG. 6 and the first plane parallel substrate 61 and the second plane parallel substrate 62 shown in FIG. 5 are rotationally symmetric by 180° with respect to the center axis parallel to the V-axis direction.

In the present variation, the first plane parallel substrate 61 and the second plane parallel substrate 62 are disposed between the chamber 32 and the rear optical system 36. Specifically, the first plane parallel substrate 61 is disposed on the first optical path P1 on the side facing the rear of the chamber 32. The second plane parallel substrate 62 is disposed on the second optical path P2 on the side facing the rear of the chamber 32. The angle of incidence of the laser light Lp incident on the first plane parallel substrate 61 is Brewster's angle. The angle of incidence of the laser light Lp incident on the second plane parallel substrate 62 is Brewster's angle.

The first plane parallel substrate 61 translates the first optical path P1 in the direction in which the first optical path P1 approaches the second optical path P2 on the side facing the chamber 32. The second plane parallel substrate 62 translates the second optical path P2 in the direction in which the second optical path P2 approaches the first optical path P1 on the side facing the chamber 32. That is, the first plane parallel substrate 61 and the second plane parallel substrate 62 translate the first optical path P1 and the second optical path P2, respectively, on the side facing the rear of the chamber 32 in the directions in which the two optical paths approach each other on the side facing the chamber 32.

According to the present variation, the rear optical system 36 can be closer to the chamber 32 than in Comparative Example. The same effect provided by the first embodiment, in which the front optical system 35 can approach the chamber 32, can therefore be provided.

### 3. Second Embodiment

### 3.1 Configuration

A laser apparatus according to a second embodiment of the present disclosure will next be described. Differences in configuration between the laser apparatuses according to the first and second embodiments will be described below.

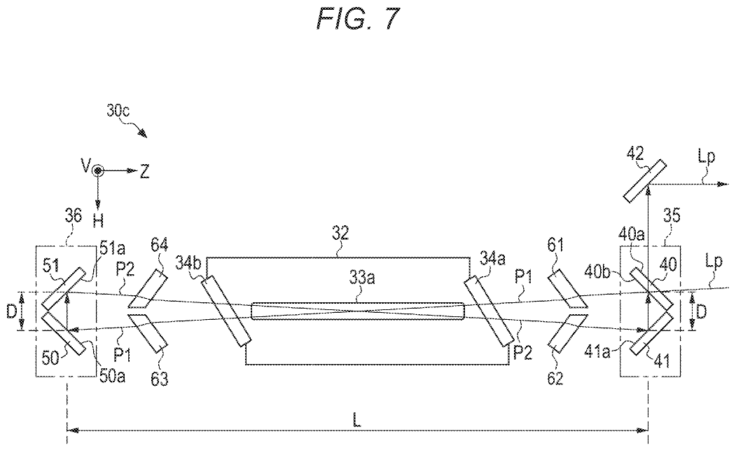

The laser apparatus according to the second embodiment differs in configuration from the laser apparatus according to the first embodiment only in that the power oscillator is configured differently. FIG. 7 schematically shows an example of the configuration of a power oscillator 30c according to the second embodiment. The power oscillator 30c differs from the power oscillator 30a according to the first embodiment in that the power oscillator 30c includes a third plane parallel substrate 63 and a fourth plane parallel substrate 64 in addition to the front optical system 35, the rear optical system 36, the first plane parallel substrate 61, and the second plane parallel substrate 62.

The first plane parallel substrate 61 and the second plane parallel substrate 62 are disposed on the side facing the front of the chamber 32, as in the first embodiment. The third plane parallel substrate 63 and the fourth plane parallel substrate 64 are disposed on the side facing the rear of the chamber 32. The third plane parallel substrate 63 and the fourth plane parallel substrate 64 have configurations that are the same as those of the first plane parallel substrate 61 and the second plane parallel substrate 62 (see FIG. 6) according to the variation of the first embodiment.

The third plane parallel substrate 63 is disposed on the first optical path P1 on the side facing the rear of the chamber 32. The fourth plane parallel substrate 64 is disposed on the second optical path P2 on the side facing the rear of the chamber 32. The angle of incidence of the laser light Lp incident on the third plane parallel substrate 63 is Brewster's angle. The angle of incidence of the laser light Lp incident on the fourth plane parallel substrate 64 is Brewster's angle.

The third plane parallel substrate 63 translates the first optical path P1 in the direction in which the first optical path P1 approaches the second optical path P2 on the side facing the chamber 32. The fourth plane parallel substrate 64 translates the second optical path P2 in the direction in which the second optical path P2 approaches the first optical path P1 on the side facing the chamber 32. That is, the third plane parallel substrate 63 and the fourth plane parallel substrate 64 translate the first optical path P1 and the second optical path P2, respectively, on the side facing the rear of the chamber 32 in the directions in which the two optical paths approach each other on the side facing the chamber 32.

### 3.2 Operation

The operation of the laser apparatus according to the second embodiment is the same as that of the laser apparatus according to the first embodiment except that the laser light Lp circling the ring resonator is shifted by the third plane parallel substrate 63 and the fourth plane parallel substrate 64 in addition to the first plane parallel substrate 61 and the second plane parallel substrate 62.

In the present embodiment, the laser light Lp output from the front optical system 35 and traveling along the first optical path P1 is shifted when passing through the first plane parallel substrate 61, and enters the chamber 32. The laser light Lp output from the chamber 32 and traveling along the first optical path P1 is shifted when passing through the third plane parallel substrate 63, and enters the rear optical system 36.

The laser light Lp output from the rear optical system 36 and traveling along the second optical path P2 is shifted when passing through the fourth plane parallel substrate 64, and enters the chamber 32. The laser light Lp output from the chamber 32 and traveling along the second optical path P2 is shifted when passing through the second plane parallel substrate 62, and enters the front optical system 35.

### 3.3 Effects

The present embodiment allows the front optical system 35 and the rear optical system 36 to approach the chamber 32. As a result, the resonator length L can be further shorter than in the first embodiment, so that the amplification efficiency is further improved.

### 4. Third Embodiment

### 4.1 Configuration

The laser apparatus according to a third embodiment of the present disclosure will next be described. Differences in configuration between the laser apparatuses according to the first and second embodiments will be described below.

The laser apparatus according to the third embodiment differs in configuration from the laser apparatus according to the first embodiment only in that the power oscillator is configured differently. FIG. 8 schematically shows an example of the configuration of a power oscillator 30d according to the third embodiment. The power oscillator 30d includes the front optical system 35, the rear optical system 36, and two first plane parallel substrates 61. The power oscillator 30d differs from the power oscillator 30a according to the first embodiment in that the first plane parallel substrate 61 and the second plane parallel substrate 62 are replaced with the two first plane parallel substrates 61.

The two first plane parallel substrates 61 are disposed on the first optical path P1. Specifically, one of the two first plane parallel substrates 61 is disposed on the first optical path P1 on the side facing the front of the chamber 32, and the other is disposed on the first optical path P1 on the side facing the rear of the chamber 32. The angle of incidence of the laser light Lp incident on each of the first plane parallel substrates 61 is Brewster's angle.

The first plane parallel substrate 61 disposed on the first optical path P1 on the side facing the front of the chamber 32 has a configuration that is the same as that of the first plane parallel substrate 61 according to the first embodiment. The first plane parallel substrate 61 disposed on the first optical path P1 on the side facing the rear of the chamber 32 has a configuration that is the same as that of the first plane parallel substrate 61 according to the variation of the first embodiment (see FIG. 6).

The first plane parallel substrates 61 each translate the first optical path P1 in the directions in which the first optical path P1 approaches the second optical path P2 on the side facing the chamber 32. That is, the two first plane parallel substrates 61 translate the first optical path P1 on the sides facing the front and rear of the chamber 32 in the directions in which the first optical path P1 and the second optical path P2 approach each other on the side facing the chamber 32.

### 4.2 Operation

The operation of the laser apparatus according to the third embodiment is the same as that of the laser apparatus according to the first embodiment except that the laser light Lp circling the ring resonator is shifted by the two first plane parallel substrates 61 in place of the first plane parallel substrate 61 and the second plane parallel substrate 62.

In the present embodiment, the laser light Lp output from the front optical system 35 and traveling along the first optical path P1 is shifted when passing through the first plane parallel substrate 61, and enters the chamber 32. The laser light Lp output from the chamber 32 and traveling along the first optical path P1 is shifted when passing through the first plane parallel substrates 61, and enters the rear optical system 36.

In the present embodiment, the laser light Lp traveling along the second optical path P2 is not shifted. The laser light Lp output from the rear optical system 36 and traveling along the second optical path P2 enters the front optical system 35 via the chamber 32.

### 4.3 Effects

In the present embodiment, the two first plane parallel substrates 61 allow the front optical system 35 and the rear optical system 36 to approach the chamber 32. When the refractive index and thickness of each of the first plane parallel substrates 61 are the same as the refractive index and thickness of each of the first plane parallel substrate 61 and the second plane parallel substrate 62 in the first embodiment, the resonator length L can be equal to that in the first embodiment. The same effects as those provided by the first embodiment can therefore be provided.

### 4.4 Variations

A variation of the power oscillator 30d according to the third embodiment will next be described. In the third embodiment, the first plane parallel substrates 61 are disposed on the first optical path P1 on the sides facing the front and rear of the chamber 32. Instead, the first plane parallel substrate 61 may be disposed on the first optical path P1 only on the side facing either the front or rear of the chamber 32.

In the third embodiment, the two first plane parallel substrates 61 are disposed on the first optical path P1, and two second plane parallel substrates 62 may instead be disposed on the second optical path P2. Specifically, one of the two second plane parallel substrates 62 may be disposed on the second optical path P2 on the side facing the front of the chamber 32, and the other may be disposed on the second optical path P2 on the side facing the rear of the chamber 32. Still instead, the second plane parallel substrate 62 may be disposed on the second optical path P2 only on the side facing either the front or rear of the chamber 32.

That is, the power oscillator of the laser apparatus according to the technology of the present disclosure only needs to include at least one plane parallel substrate disposed on the first optical path P1 or the second optical path P2.

### 5. Fourth Embodiment

### 5.1 Configuration

The laser apparatus according to a fourth embodiment of the present disclosure will next be described. Differences in configuration between the laser apparatuses according to the first and second embodiments will be described below.

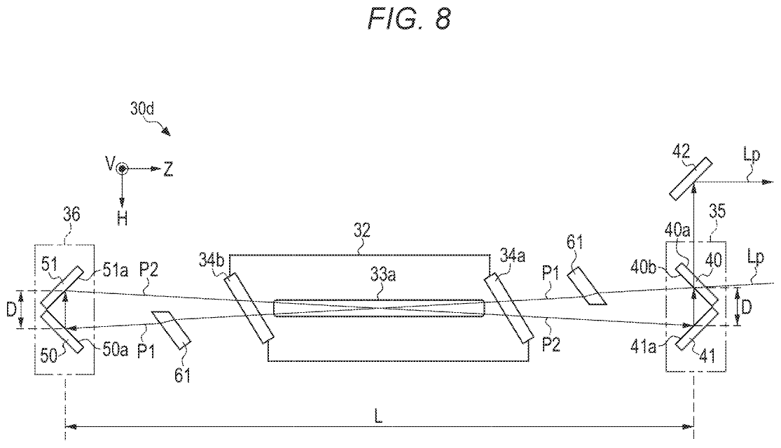

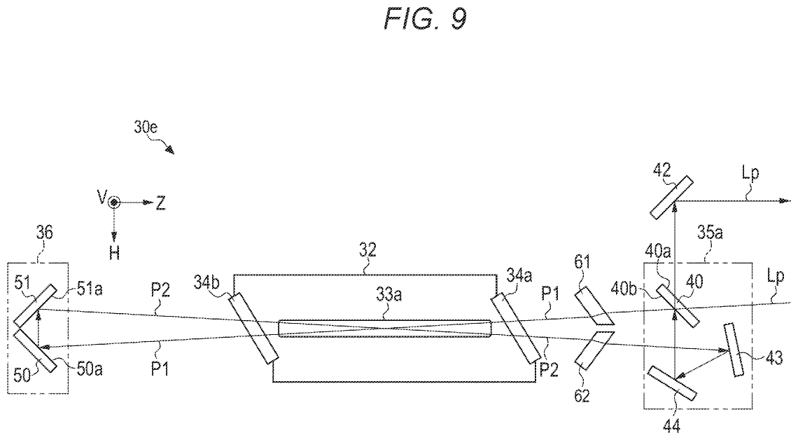

The laser apparatus according to the fourth embodiment differs from the laser apparatus according to the first embodiment in configuration only in that the power oscillator is configured differently. FIG. 9 schematically shows an example of the configuration of a power oscillator 30e according to the fourth embodiment. In the power oscillator 30e, a front optical system 35a differs in configuration from the front optical system 35 according to the first embodiment. The other configurations of the power oscillator 30e are the same as those of the power oscillator 30a according to the first embodiment.

The front optical system 35a includes the output coupler 40, a first highly reflective mirror 43, and a second highly reflective mirror 44. The configuration of the output coupler 40 is the same as that in the first embodiment. The first highly reflective mirror 43 is disposed to reflect the laser light Lp, which travels along the second optical path P2 and enters the front optical system 35a, toward the second highly reflective mirror 44. The second highly reflective mirror 44 is disposed to reflect the laser light Lp, which is incident from the first highly reflective mirror 43, toward the second surface 40b of the output coupler 40.

The output coupler 40 transmits part of the laser light Lp incident on the second surface 40b from the second highly reflective mirror 44, and reflects part of the laser light Lp and causes the laser light Lp to travel along the first optical path P1.

In the first embodiment, the ring resonator includes four mirrors being the output coupler 40, the highly reflective mirror 41, the first highly reflective mirror 50, and the second highly reflective mirror 51. In contrast, in the present embodiment, the ring resonator includes five mirrors being the output coupler 40, the first highly reflective mirror 43, the second highly reflective mirror 44, the first highly reflective mirror 50, and the second highly reflective mirror 51.

### 5.2 Operation

The operation of the laser apparatus according to the fourth embodiment is the same as that of the laser apparatus according to the first embodiment except that the laser light Lp having entered the front optical system 35a is reflected off the first highly reflective mirror 43 and the second highly reflective mirror 44 and is then incident on the output coupler 40.

In the present embodiment, the laser light Lp having entered the front optical system 35a from the chamber 32 via the second plane parallel substrate 62 is reflected off the first highly reflective mirror 43 and the second highly reflective mirror 44 and is incident on the output coupler 40. Part of the laser light Lp incident on the output coupler 40 passes through the output coupler 40 and exits out of the front optical system 35a toward the highly reflective mirror 42, is reflected off the highly reflective mirror 42, and exits out of the laser apparatus. The remainder of the laser light Lp incident on the output coupler 40 is reflected off the output coupler 40 and exits out of the front optical system 35a.

### 5.3 Effects

In the present embodiment, the ring resonator includes five mirrors, so that the beam profile of the laser light Lp is flipped in the form of a mirror image whenever the laser light Lp circles the ring resonator once. That is, the beam profile of the laser light Lp output from the power oscillator 30e is flipped in the form of a mirror image on a circulation basis, so that the spatial coherency of the laser light Lp decreases. Speckles produced on the reticle are thus suppressed when the laser apparatus is used as a light source for exposure.

Furthermore, even when the five mirrors that constitute the ring resonator are angularly misaligned, the beam profile of the laser light Lp is flipped in the form of a mirror image on a circulation basis, so that accumulation of the angular misalignment components of the mirrors is advantageously suppressed.

### 5.4 Variations

The front optical system 35a according to the present embodiment is not limited to the front optical system 35 according to the first embodiment, but may be replaced with the front optical system 35 according to the second embodiment, the third embodiment, or any of the variations thereof.

### 6. Crystal Orientation of Plane Parallel Substrates

Variations of the crystal orientation of the plane parallel substrates will next be described. A plurality of preferable crystal orientations will be described below in relation to the laser light Lp incident on the first plane parallel substrate 61. The same holds true for the plane parallel substrates other than the first plane parallel substrate 61.

### 6.1 Crystal Structure

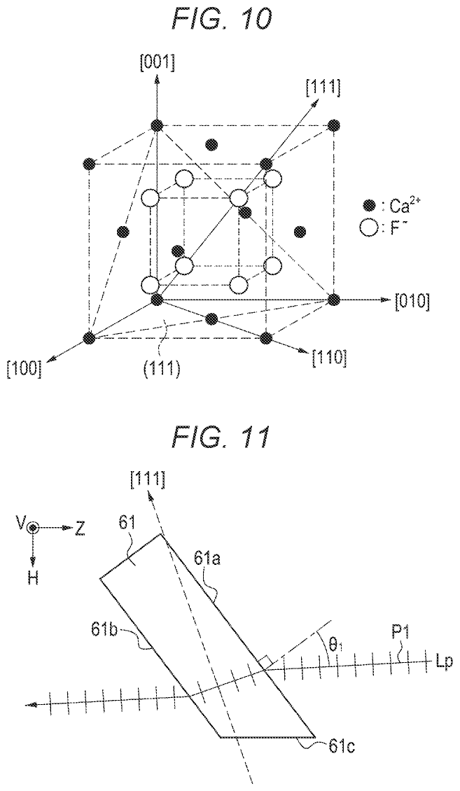

FIG. 10 shows the structure of the CaF₂ crystal that forms the first plane parallel substrate 61. In the CaF₂ crystal, the calcium ions (Ca²⁺) form a face-centered cubic lattice structure, and the fluorine ions (F⁻) form a simple cubic lattice structure. The calcium ions are each located at the body center of the cube including the fluorine ions. The fluorine ions are each located at the center of the regular tetrahedron formed by the calcium ions.

In the following description, a crystal plane in a cubic crystal is denoted as (hkl), and the direction of an axis is denoted as [uvw]. These represent a specific plane and axis in the crystal. A term <uvw>includes all axes equivalent to the [uvw] axis, that is, axes having the same relationship with respect to the coordinate axes.

The CaF₂ crystal has threefold symmetry with respect to the [111] axis as the axis of symmetry. That is, when the CaF₂ crystal is viewed from directly above the [111] axis, the angle between the [100] axis and the [010] axis is 120°, and the angle between the [100] axis and the [001] axis is 240°. The crystal growth direction of the CaF₂ crystal is the [111] axis direction, and the (111) plane is cleavable.

In each example below, the laser light Lp is incident as P-polarized light on the first surface 61a of the first plane parallel substrate 61. The angle of incidence θ₁ of the laser light Lp incident on the first surface 61a is Brewster's angle, as described above. When the refractive index n of the CaF₂ crystal is 1.501958, Brewster's angle is about 56.34°.

### 6.2 First Crystal Orientation

FIG. 11 shows a first preferable crystal orientation in relation to the laser light Lp incident on the first plane parallel substrate 61. In FIG. 11, the first plane parallel substrate 61 is so formed that the [111] axis coincides with an electric field axis of the laser light Lp passing through the interior of the first plane parallel substrate 61. That is, the [111] axis is parallel to the plane of incidence of the first plane parallel substrate 61 and parallel to the direction perpendicular to the optical path axis of the laser light Lp passing through the interior of the first plane parallel substrate 61.

In the present disclosure, the electric field axis is an axis parallel to the electric field vector of linearly polarized light. When the laser light Lp contains an S-polarized component in addition to the P-polarized component polarized in the direction parallel to the plane of incidence, the electric field axis is an axis parallel to the electric field vector of the P-polarized component.

The state in which the [111] axis coincides with the electric field axis of the laser light Lp reduces the amount of absorption of the laser light Lp in the first plane parallel substrate 61, achieving the effect of reducing thermal stress and the amount of birefringence (see U.S. patent Application Publication No. 2020/0067257 for details).

Note that the [111] axis is equivalent to any axis other than the [111] axis contained in <111>. The first plane parallel substrate 61 therefore only needs to be so formed that the electric field axis of the P-polarized component of the laser light Lp passing through the interior thereof coincides with one axis contained in <111>.

### 6.3 Second Crystal Orientation

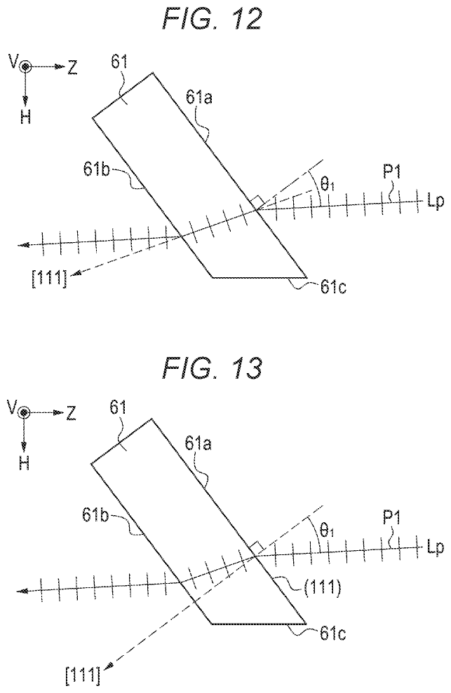

FIG. 12 shows a second preferable crystal orientation in relation to the laser light Lp incident on the first plane parallel substrate 61. In FIG. 12, the first plane parallel substrate 61 is so formed that the [111] axis coincides with the optical path axis of the laser light Lp passing through the interior of the first plane parallel substrate 61. That is, the [111] axis is parallel to the plane of incidence of the first plane parallel substrate 61 and parallel to the optical path axis of the laser light Lp passing through the interior of the first plane parallel substrate 61.

The state in which the [111] axis coincides with the optical path axis of the laser light Lp causes the laser light Lp to be incident at right angles on the (111) plane, which is a cleavage plane, so that a change in the polarization state of the laser light Lp, nonuniformity of the wavefront of the laser light Lp, and other disadvantages can be reduced (see U.S. Pat. No. 6,181,724 for details).

Note that the first plane parallel substrate 61 only needs to be so formed that the optical path axis of the laser light Lp passing through the interior thereof coincides with one axis contained in <111>.

6.4 Third crystal Orientation

FIG. 13 shows a third preferable crystal orientation in relation to the laser light Lp incident on the first plane parallel substrate 61. In FIG. 13, the first plane parallel substrate 61 is so formed that the [111] axis is perpendicular to the first surface 61a and the second surface 61b. That is, the first surface 61a and the second surface 61b are each the (111) plane. The first plane parallel substrate 61 is disposed at a position where the first plane parallel substrate 61 is rotated by 60° around the [111] axis with respect to an arrangement in which the laser light Lp passes through the plane containing the [111] and [001] axes.

Disposing the first plane parallel substrate 61 as described above provides the effect of reducing the thermal stress caused by the laser light Lp (see U.S. patent Application Publication No. 2011/0158281 for details). The state in which the first surface 61a and the second surface 61b are the (111) plane, which is a cleavage plane, facilitates the manufacture of the first plane parallel substrate 61.

Note that the first plane parallel substrate 61 only needs to be disposed at a position where a surface of the first plane parallel substrate 61 is perpendicular to a first axis that is one axis contained in <111>and the first plane parallel substrate 61 is rotated by 60° around the first axis with respect to an arrangement in which the laser light Lp passes through the plane containing the first axis and a second axis that is one axis contained in <001>. One example of the first axis is the [111] axis, and one example of the second axis is the [001] axis.

### 7. Variation of Master Oscillator

A variation of the master oscillator 10 will next be described. The laser apparatus includes the master oscillator 10 that an excimer laser apparatus constitutes in the embodiments described above, and the master oscillator 10 may be modified in various ways.

### 7.1 Configuration

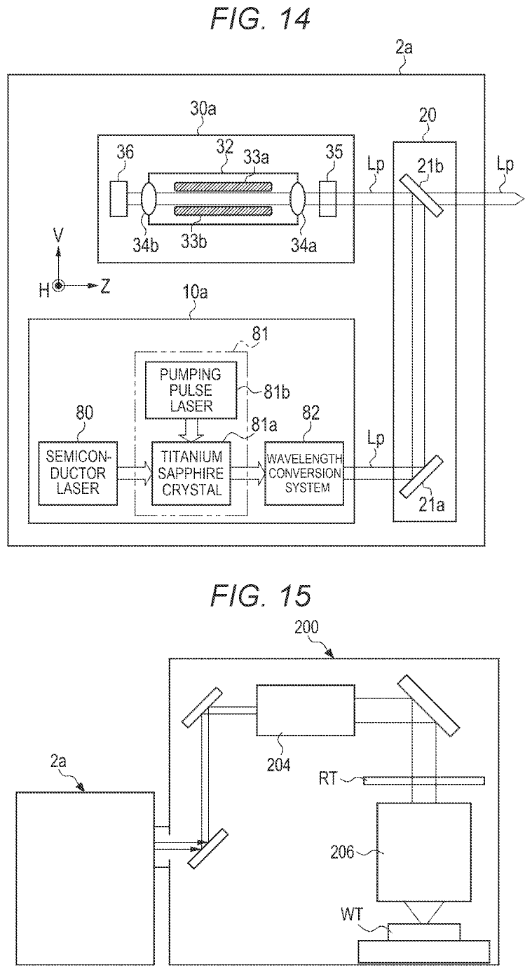

FIG. 14 schematically shows an example of the configuration of a laser apparatus 2a according to the variation. The laser apparatus 2a includes a master oscillator 10a, the MO beam steering unit 20, and the power oscillator 30a. The MO beam steering unit 20 and the power oscillator 30a have configurations that are the same as those in the first embodiment.

The master oscillator 10a is a solid-state laser apparatus and includes a semiconductor laser 80, which outputs seed light, a titanium sapphire amplifier 81, which amplifies the seed light, and a wavelength conversion system 82.

The semiconductor laser 80 is a distributed feedback semiconductor laser that outputs continuous wave (CW) laser light having a wavelength of 773.6 nm as the seed light. Changing the temperature setting of the semiconductor laser 80 can change the wavelength at which the semiconductor laser 80 oscillates.

The titanium sapphire amplifier 81 includes a titanium-sapphire crystal 81a and a pumping pulse laser 81b. The titanium sapphire crystal 81a is disposed on the optical path of the seed beams. The pumping pulse laser 81b is a laser apparatus that outputs the second harmonic of the laser light from a YLF laser.

The wavelength conversion system 82 is a wavelength conversion system that generates fourth harmonic light and includes an LBO (Li₃BO₅) crystal and a KBBF (KBe₂BO₃F₂) crystal. The crystals are each placed on a rotary stage that is not shown and configured to be capable of changing the angle of incidence of the seed light incident on the crystal.

### 7.2 Operation

In the titanium sapphire amplifier 81, the pumping pulse laser 81b converts the CW laser light as the seed light input to the titanium sapphire crystal 81a into pulse laser light based on a trigger signal input from a controller (not shown), and outputs the pulse laser light. The pulse laser light output from the titanium sapphire amplifier 81 is input to the wavelength conversion system 82. The wavelength conversion system 82 converts the input pulse laser light having the wavelength of 773.6 nm into pulse laser light having a wavelength of 193.4 nm and outputs the resultant laser light as the laser light Lp toward the MO beam steering unit 20.

In the present variation, the power oscillator 30a is an ArF excimer amplifier and amplifies the laser light Lp having the wavelength of 193.4 nm and input from the MO beam steering unit 20.

### 7.3 Others

The master oscillator 10a may be a solid-state laser apparatus that outputs pulse laser light having a wavelength of 248.4 nm, and the power oscillator 30a may be a KrF excimer amplifier. In this case, the semiconductor laser 80 outputs CW laser light having a wavelength of 745.2 nm, and the titanium sapphire amplifier 81 converts the CW laser light input from the semiconductor laser 80 into pulse laser light, and outputs the pulse laser light. In this case, the wavelength conversion system 82 is a wavelength conversion system that generates third harmonic light and includes an LBO crystal and a CLBO (CsLiB₆O₁₀) crystal. The wavelength conversion system 82 outputs pulse laser light having the wavelength of 248.4 nm as the laser light Lp by causing the LBO crystal to generate second harmonic light and causing the CLBO crystal to generate third harmonic light.

The laser apparatus 2a may include any of the power oscillators according to the embodiments and variations described above in place of the power oscillator 30a.

### 8. Electronic Device Manufacturing Method

FIG. 15 schematically shows an example of the configuration of an exposure apparatus 200. The exposure apparatus 200 includes an illumination optical system 204 and a projection optical system 206. The illumination optical system 204, for example, illuminates a reticle pattern of a reticle that is not shown but is placed on a reticle stage RT with the laser light Lp having entered the exposure apparatus 200 from the laser apparatus 2a. The projection optical system 206 performs reduction projection on the laser light Lp having passed through the reticle to bring the laser light Lp into focus on a workpiece that is not shown but is placed on a workpiece table WT. The workpiece is a photosensitive substrate onto which a photoresist has been applied, such as a semiconductor wafer.

The exposure apparatus 200 translates the reticle stage RT and the workpiece table WT in synchronization with each other to expose the workpiece to the laser light Lp having reflected the reticle pattern. Semiconductor devices can be manufactured by transferring the reticle pattern onto the semiconductor wafer in the exposure step described above and then carrying out a plurality of other steps. The semiconductor devices are an example of the “electronic devices” in the present disclosure.

The laser apparatus that outputs the laser light Lp to the exposure apparatus 200 may be any of the laser apparatuses according to the embodiments and variations described above.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A laser apparatus comprising:
an oscillator configured to output laser light;
an amplifier configured to amplify the laser light in a chamber including a pair of discharge electrodes;
a front optical system and a rear optical system that are disposed at positions where the front and rear optical systems face each other with the chamber sandwiched therebetween and constitute a ring resonator having a first optical path and a second optical path that intersect with each other between the pair of discharge electrodes; and
a first plane parallel substrate disposed on the first or second optical path,
the first optical path being an optical path via which the front optical system outputs the laser light incident from the oscillator toward the rear optical system,
the second optical path being an optical path via which the rear optical system outputs the laser light incident via the first optical path toward the front optical system, and
the first plane parallel substrate being configured to translate the first and second optical paths in such a way that the first and second optical paths approach each other on a side facing the chamber.

2. The laser apparatus according to claim 1,
wherein the first and second optical paths are contained in a plane perpendicular to a discharge direction in which discharge occurs between the pair of discharge electrodes, and
the first plane parallel substrate is configured to translate the first and second optical paths in a direction perpendicular to the discharge direction.

3. The laser apparatus according to claim 1, further comprising:
a second plane parallel substrate disposed on the second optical path, wherein
the first plane parallel substrate is disposed on the first optical path.

4. The laser apparatus according to claim 3,
wherein the first and second plane parallel substrates are disposed between the chamber and the front optical system, and configured to translate the first and second optical paths in such a way that the first and second optical paths approach each other on the side facing the chamber.

5. The laser apparatus according to claim 4, further comprising:
a third plane parallel substrate disposed on the first optical path between the chamber and the rear optical system; and
a fourth plane parallel substrate disposed on the second optical path between the chamber and the rear optical system,
wherein the third and fourth plane parallel substrates are configured to translate the first and second optical paths in such a way that the first and second optical paths approach each other on the side facing the chamber.

6. The laser apparatus according to claim 3,
wherein the first and second plane parallel substrates are disposed between the chamber and the rear optical system, and configured to translate the first and second optical paths in such a way that the first and second optical paths approach each other on the side facing the chamber.

7. The laser apparatus according to claim 3,
wherein the first and second plane parallel substrates each have an inclining surface inclining with respect to a planar surface on which the laser light is incident, and the inclining surface of the first plane parallel substrate faces the inclining surface of the second plane parallel substrate.

8. The laser apparatus according to claim 7,
wherein the inclining surface of the first plane parallel substrate is separate from the inclining surface of the second plane parallel substrate.

9. The laser apparatus according to claim 1,
wherein the front optical system includes an output coupler and a highly reflective mirror, and
the output coupler is configured to transmit the laser light incident from the oscillator to cause the laser light to travel along the first optical path.

10. The laser apparatus according to claim 9,
wherein the highly reflective mirror is configured to reflect the laser light traveling along the second optical path and entering the front optical system toward the output coupler, and
the output coupler is configured to transmit part of the laser light incident from the highly reflective mirror to cause the part of the laser light to exit out of the front optical system and reflect remaining part of the laser light to cause the remaining part of the laser light to travel along the first optical path.

11. The laser apparatus according to claim 1,
wherein the front optical system includes an output coupler, a first highly reflective mirror, and a second highly reflective mirror, and
the output coupler is configured to transmit the laser light incident from the oscillator to cause the laser light to travel along the first optical path.

12. The laser apparatus according to claim 11,
wherein the first highly reflective mirror is configured to reflect the laser light traveling along the second optical path and entering the front optical system toward the second highly reflective mirror,
the second highly reflective mirror is configured to reflect the laser light incident from the first highly reflective mirror toward the output coupler, and
the output coupler is configured to transmit part of the laser light incident from the second highly reflective mirror to cause the part of the laser light to exit out of the front optical system and reflect remaining part of the laser light to cause the remaining part of the laser light to travel along the first optical path.

13. The laser apparatus according to claim 1,
wherein the rear optical system includes a first highly reflective mirror and a second highly reflective mirror,
the first highly reflective mirror is configured to reflect the laser light traveling along the first optical path and entering the rear optical system toward the second highly reflective mirror, and
the second highly reflective mirror is configured to reflect the laser light incident from the first highly reflective mirror to cause the laser light to travel along the second optical path.

14. The laser apparatus according to claim 1,
wherein an angle of incidence of the laser light incident on the first plane parallel substrate is Brewster's angle.

15. The laser apparatus according to claim 14,
wherein the first plane parallel substrate is made of calcium fluoride.

16. The laser apparatus according to claim 15,
wherein the first plane parallel substrate is so configured that an electric field axis of a P-polarized component of the laser light passing through an interior of the first plane parallel substrate coincides with one axis contained in <111>.

17. The laser apparatus according to claim 15,
wherein the first plane parallel substrate is so configured that an optical path axis of the laser light passing through an interior of the first plane parallel substrate coincides with one axis contained in <111>.

18. The laser apparatus according to claim 15,
wherein the first plane parallel substrate is disposed at a position where a surface of the first plane parallel substrate is perpendicular to a first axis that is one axis contained in <111>and the first plane parallel substrate is rotated by 60° around the first axis with respect to an arrangement in which the laser light passes through a plane containing the first axis and a second axis that is one axis contained in <001>.

19. The laser apparatus according to claim 1,
wherein the oscillator is a solid-state laser apparatus.

20. An electronic device manufacturing method comprising:
generating laser light by using a laser apparatus;
outputting the laser light to an exposure apparatus; and
exposing a photosensitive substrate to the laser light in the exposure apparatus to manufacture electronic devices, the laser apparatus including
an oscillator configured to output laser light,
an amplifier configured to amplify the laser light in a chamber including a pair of discharge electrodes,
a front optical system and a rear optical system that are disposed at positions where the front and rear optical systems face each other with the chamber sandwiched therebetween and constitute a ring resonator having a first optical path and a second optical path that intersect with each other between the pair of discharge electrodes, and
a first plane parallel substrate disposed on the first or second optical path,
the first optical path being an optical path via which the front optical system outputs the laser light incident from the oscillator toward the rear optical system,
the second optical path being an optical path via which the rear optical system outputs the laser light incident via the first optical path toward the front optical system,
the first plane parallel substrate being configured to translate the first and second optical paths in such a way that the first and second optical paths approach each other on a side facing the chamber.
